(19) United States
(12) Patent Application Publication
(10) Pub. No.: US 2026/0255953 A1
(43) Pub. Date: Aug. 27, 2026

(54) SEMICONDUCTOR DEVICE

(71) Applicant: Socionext Inc., Kanagawa (JP)

(72) Inventors: Hirotaka TAKENO, Yokohama (JP); Atsushi OKAMOTO, Yokohama (JP); Wenzhen WANG, Yokohama (JP)

(21) Appl. No.: 19/648,430

(22) Filed: Apr. 15, 2026

Related U.S. Application Data
(63) Continuation of application No. PCT/JP2023/037784, filed on Oct. 19, 2023.

(51) Int. Cl. H10W 20/43; H10D 84/83; H10W 20/20; H10W 20/40

(52) U.S. Cl. CPC H10W 20/43; H10D 84/832; H10W 20/213; H10W 20/481

(57) ABSTRACT

A semiconductor device includes a substrate, a first power supply line and a second power supply line extending in a first direction on a first surface of the substrate, a first transistor disposed on a second surface of the substrate, the first transistor being electrically connected between the first power supply line and the second power supply line, a second transistor disposed above the first transistor, and sharing a gate with the first transistor, and a first conductive wall extending in the first direction and disposed offset from the first power supply line and the second power supply line in a second direction, wherein the first transistor includes a first semiconductor layer and a second semiconductor layer with the gate interposed therebetween, the first semiconductor layer is electrically connected to the first power supply line, and the second semiconductor layer is electrically connected to the second power supply line.

### CROSS-REFERENCE TO RELATED APPLICATION

This application is a continuation application of International Application No. PCT/JP2023/037784, filed on October 19, 2023, and designated the U.S., the entire contents of which are incorporated herein by reference.

### BACKGROUND OF THE INVENTION

The disclosures herein relate to semiconductor devices.

There is a technology called CFET (Complementary Field Effect Transistor) which forms a CMOS (Complementary Metal-Oxide-Semiconductor) by stacking transistors in a direction perpendicular to a substrate. With the use of CFETs, a cell area of a CMOS basic cell is significantly reduced, and a semiconductor device is downsized. In a technology called BS-PDN (Backside Power Delivery Network) which supplies a power supply voltage to a circuit on a front surface of a semiconductor substrate from a back surface of the substrate, a configuration is used in which a Through Silicon Via (TSV) penetrating the substrate is directly connected to a source/drain of a transistor. There is a technology called a power wall in which a conductive wall is formed over the height of the upper and lower transistors of a CFET to supply power to each transistor. There is a technology in which a power switch circuit for controlling on and off of supply of a power supply voltage is provided in a circuit such as a standard cell.

In a circuit that supplies power to a CFET via a power wall, how to lay out a power switch circuit has not been studied in detail. The present disclosure aims to provide a semiconductor device having a configuration for supplying power via a power wall and having a power switch circuit effectively laid out.

### CITATION LIST

### PATENT LITERATURE

[PTL 1] U.S. Patent Application Publication No. 2022/0068921

[PTL 2] U.S. Patent Application Publication No. 2023/0178435

[PTL 3] U.S. Patent Application Publication No. 2023/0067311

[PTL 4] U.S. Patent Application Publication No. 2022/0123023

[PTL 5] U.S. Patent Application Publication No. 2022/0181258

[PTL 6] WO 2020/065916

[PTL 7] WO 2020/066797

[PTL 8] WO 2020/217396

[PTL 9] WO 2020/217400

[PTL 10] U.S. Patent Application Publication No. 2021/0366902

[PTL 11] U.S. Patent Application Publication No. 2022/0102479

[PTL 12] U.S. Patent Application Publication No. 2021/0210600

[PTL 13] U.S. Patent No. 10950546

[PTL 14] U.S. Patent No. 11004789

### SUMMARY OF THE INVENTION

A semiconductor device includes a substrate, a first power supply line and a second power supply line extending in a first direction in plan view on a first surface of the substrate, a first transistor disposed on a second surface of the substrate opposite to the first surface, the first transistor being electrically connected between the first power supply line and the second power supply line, a second transistor disposed above the first transistor, and sharing a gate with the first transistor, and a first conductive wall extending in the first direction and disposed offset from the first power supply line and the second power supply line in a second direction different from the first direction in plan view, wherein in plan view, the first transistor includes a first semiconductor layer disposed at a position overlapping the first power supply line and a second semiconductor layer disposed at a position overlapping the second power supply line, with the gate interposed therebetween, the first semiconductor layer is electrically connected to the corresponding one of the first power supply lines via a first through via penetrating the substrate, and the second semiconductor layer is electrically connected to the corresponding one of the second power supply lines via a second through via penetrating the substrate.

A semiconductor device having a configuration for supplying power via a power wall and having a power switch circuit effectively laid out is provided.

### BRIEF DESCRIPTION OF THE DRAWINGS

FIG. 1 is a schematic diagram illustrating an outline of a layout of a semiconductor device of an embodiment;

FIG. 2 is a schematic cross-sectional view illustrating an example of an interconnect structure of a circuit region of the semiconductor device;

FIG. 3 is a drawing illustrating an overview of the semiconductor device of the embodiment;

FIG. 4 is a plan view illustrating a backside metal (BSM) of the semiconductor device of the embodiment;

FIG. 5 is a plan view illustrating a bottom layer of the semiconductor device of the embodiment;

FIG. 6 is a plan view illustrating a top layer of the semiconductor device of the embodiment;

FIG. 7 is a cross-sectional view of FIGS. 4 to 6 taken along a line X1-X1′;

FIG. 8 is a cross-sectional view of FIGS. 4 to 6 taken along a line Y1-Y1′;

FIG. 9 is a plan view illustrating a bottom layer of a semiconductor device of a first modification example; and

FIG. 10 is a plan view illustrating a top layer of a semiconductor device of a second modification example.

### DESCRIPTION OF THE PREFERRED EMBODIMENTS

In an embodiment, in a semiconductor device in which a power wall is used for a part of power supply lines for supplying a power supply voltage to a CFET, a power switch circuit having an effective layout is provided. In the following, a specific configuration of the semiconductor device of the present embodiment will be described with reference to the accompanying drawings. In addition, the embodiments described below are not intended to limit the invention but are examples, and all features and combinations thereof described in the embodiments are not necessarily essential to the invention. The sizes and positional relationships of the components shown in the drawings may be exaggerated to facilitate understanding of the invention. In the drawings, the same constituent elements are denoted with the same reference numerals, and redundant description thereabout may be omitted.

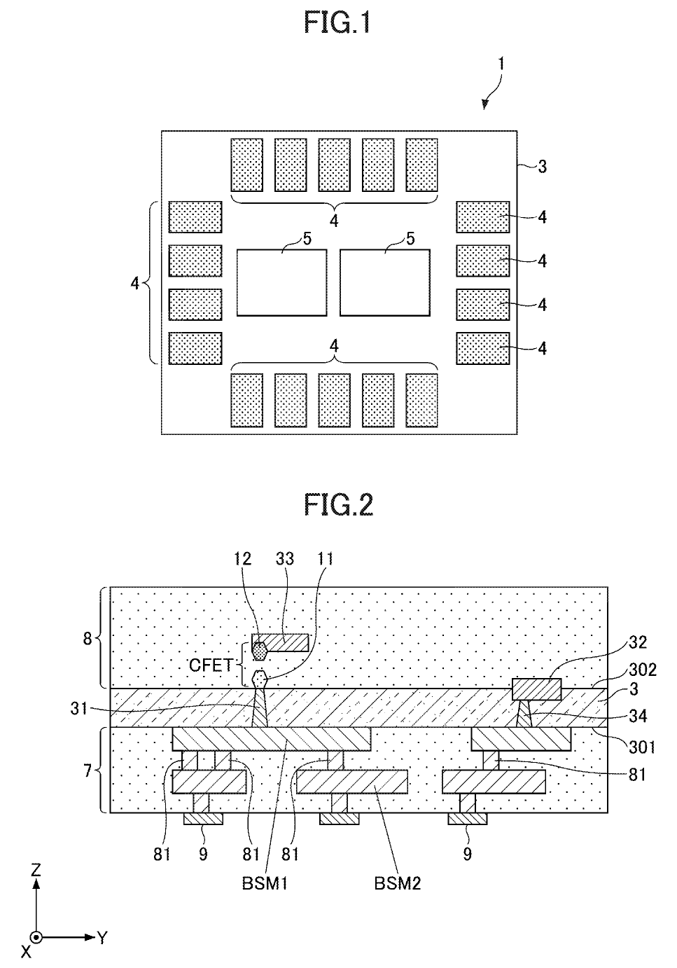

FIG. 1 is a schematic diagram illustrating an outline of a layout of a semiconductor device 1 according to the embodiment. The semiconductor device 1 has one or more circuit regions 5 disposed on a substrate 3 and a plurality of input and output (I/O) cell regions 4 disposed on the substrate 3. The circuit region 5 may have a standard cell including a plurality of logic circuits, or may have other circuits such as a gate array, SRAM (Static Random Access Memory), and analog circuits.

FIG. 2 is a schematic cross-sectional view illustrating an example of an interconnect structure of the circuit region 5 of the semiconductor device 1. In a coordinate system of FIG. 2, a plane parallel to the substrate 3 is referred to as an XY-plane, and a direction perpendicular to the substrate 3, that is, a stacking direction is referred to as a Z-direction. The semiconductor device 1 has a first interconnect layer 7 on a back surface 301 of the substrate 3 and a second interconnect layer 8 on a front surface 302 of the substrate. The semiconductor device 1 supplies a power supply voltage from the back surface 301 of the substrate 3 to a circuit on the front surface 302 side of the substrate 3. Here, the back surface 301 of the substrate 3 is referred to as a “first surface” and the front surface 302 is referred to as a “second surface”. A CFET having a first transistor 11 and a second transistor 12 in a direction perpendicular to the substrate 3 is disposed on the front surface 302 side of the substrate 3. The lower first transistor 11 may be referred to as a “bottom transistor” and the upper second transistor may be referred to as a “top transistor”. In the present figure, sources and drains (hereinafter referred to as “source/drain”, as appropriate) of the first transistor 11 and the second transistor 12 are extended in an X-direction perpendicular to the drawing.

In the first interconnect layer 7, a power supply line for supplying an operating voltage of a circuit or a reference voltage lower than the operating voltage is formed. In the example shown in FIG. 2, a first layer interconnect (BSM1) on the back surface 301 of the substrate 3 and a second layer interconnect (BSM2) on the back surface 301 are provided. An interconnect BSM1 of the first layer and an interconnect BSM2 of the second layer are connected via a via plug 81. A pad 9 serving as an external connection terminal is formed on the lowermost surface of the first interconnect layer 7. The first interconnect layer 7 may be an interconnect layer formed directly on the back surface 301 of the substrate 3 or an interconnect layer formed on another chip (i.e., a substrate) bonded to the back surface 301 of the substrate 3.

The interconnects BSM1 and BSM2 of the first interconnect layer 7 are connected to the semiconductor layer of the first transistor 11 of CFET via a through via 31 penetrating the substrate 3. The interconnects BSM1 and BSM2 of the first interconnect layer 7 are connected to the semiconductor layer of the second transistor 12 of CFET via a through via (not shown) provided in the substrate 3 and an interconnect 33 formed in the second interconnect layer 8. An embedded interconnect 32 connected to a through via 34 may be provided on the front surface 302 side of the substrate 3. The connection between the interconnect on the back surface 301 of the substrate 3 and the second transistor 12 on the upper side of CFET may be achieved, as will be described later, by a conductive wall (also referred to as a “power wall”) extending vertically from the back surface 301 toward the front surface 302 of the substrate 3 and the interconnect 33 connected to the conductive wall.

### OUTLINE OF SEMICONDUCTOR DEVICE OF EMBODIMENT

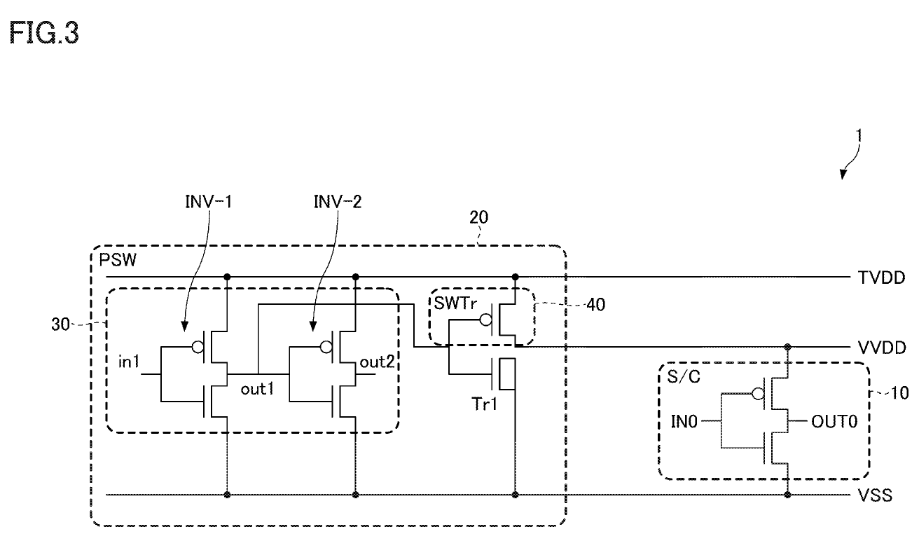

FIG. 3 is a drawing illustrating an overview of the semiconductor device 1. The semiconductor device 1 includes a standard cell 10 and a power switch circuit (referred to as “PSW” in the figure) 20 for switching on and off the supply of power to the standard cell 10. The standard cell 10 has a circuit of the smallest unit for performing a basic operation by various logic circuits such as NAND, NOR, AOI (AND-OR INV), and flip-flop. In the example of FIG. 3, the standard cell 10 is an inverter, but it is not limited to this example, and other logic circuits may be used.

The power switch circuit 20 includes a switch transistor 40 for switching on and off the supply of power and a control circuit 30 for controlling the switch transistor (referred to as “SWTr” in the figure) 40. In a configuration in which the power switch circuit 20 switches on and off the supply of power to circuits such as the standard cell 10, three types of power supply lines are used: a true VDD (TVDD), a virtual VDD (VVDD), and VSS. TVDD and VVDD supply, for example, an operating voltage on the high voltage side. The power supply line VSS supplies a reference voltage lower than the operating voltage. As will be described later, the power supply line VSS has a conductive wall (or power wall) perpendicular to the substrate.

The standard cell 10 is electrically connected between VSS and VVDD. The power switch circuit 20 is electrically connected between VSS and TVDD. If the power supply voltage is always supplied to the standard cell 10 even when the standard cell 10 is not in use, leakage may occur and power consumption may increase. In order to prevent this, the standard cell 10 is connected to VVDD, which is a virtual power supply line, and the power supply voltage is supplied from TVDD to VVDD when necessary. The power supply from TVDD to VVDD to which the standard cell is connected is executed by the switch transistor 40 based on a command from the control circuit 30. The switch transistor 40 is composed of a PMOS transistor in this example, and its source is connected to TVDD, and its drain is connected to VVDD.

The control circuit 30 is provided between TVDD and VSS, and an output of an inverter INV-1 included in the control circuit 30 is input to the gate of the switch transistor 40. The switch transistor 40 switches on and off the supply of the power supply voltage from TVDD to VVDD based on a control signal from the control circuit 30. In the configuration example of FIG. 3, the switch transistor 40 is controlled by a signal “out1” from a node between two inverters INV-1 and INV-2, but the control circuit 30 is not limited to this example and may have any configuration for controlling the switching operation of the supply of the power supply voltage of the switch transistor 40.

A transistor Tr1 similar to NMOS is connected to the gate of the switch transistor 40 formed of PMOS. The switch transistor 40 and the transistor Tr1 are included in a CFET stacked in a direction perpendicular to the substrate and connected to a common gate. In FIG. 3, portions corresponding to the source and drain of the transistor Tr1 are connected to VSS but may be floating. The transistor Tr1 may be a dummy top transistor formed by a process common to the standard cell 10 and CFET of the control circuit 30. Further, instead of forming a dummy top transistor, formation of some top transistors may be omitted.

When switching on and off the power supply to the standard cell 10 in a circuit using three types of power supply lines, that is, TVDD, VVDD, and VSS, it is important to design a specific interconnect of the power switch circuit 20. Since a VSS interconnect formed as a conductive wall is connected to both the power switch circuit 20 and the standard cell 10, an efficient connection structure is required. In particular, an efficient layout is required in which the source of the switch transistor 40 is connected to TVDD, the drain is connected to VVDD, and the standard cell 10 is connected between VVDD and VSS.

### SPECIFIC CONFIGURATION OF SEMICONDUCTOR DEVICE

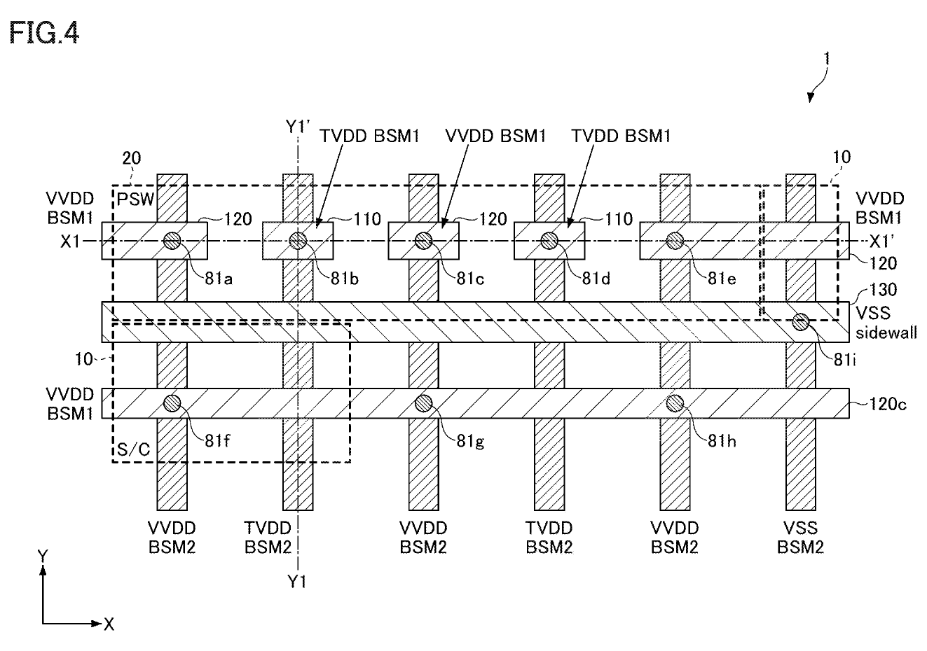

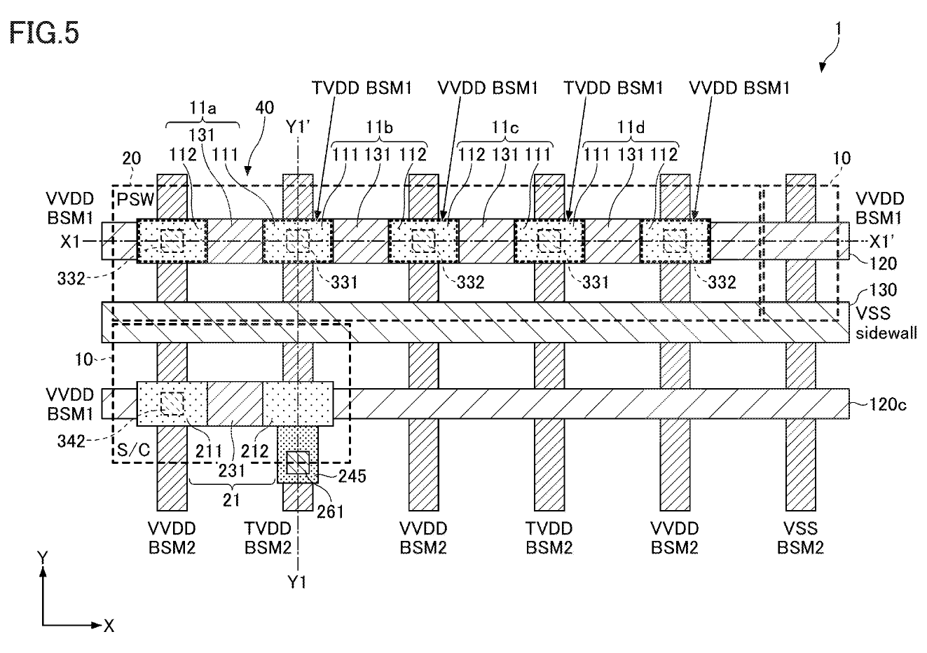

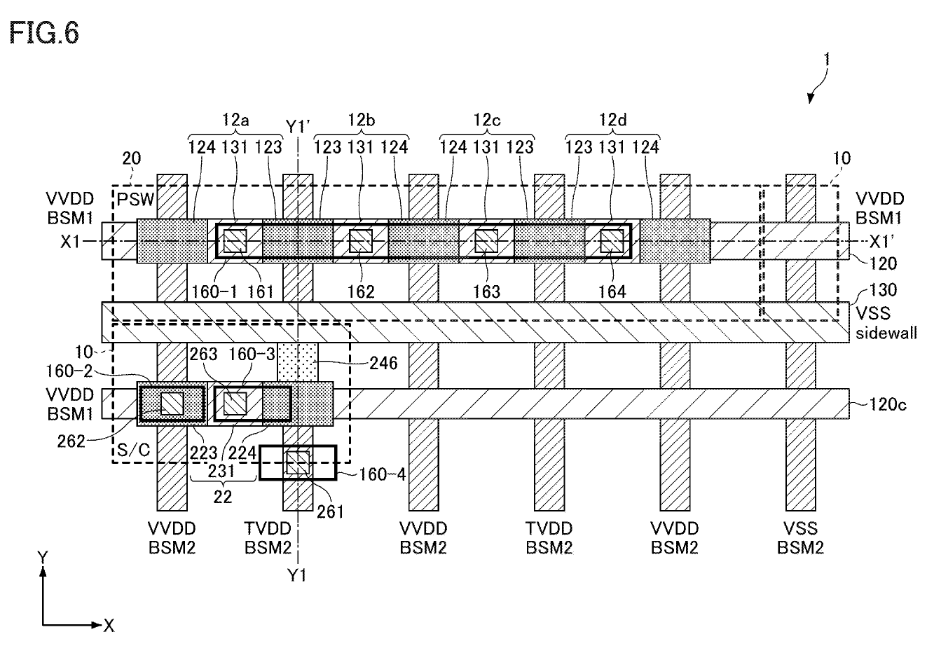

FIG. 4 is a plan view illustrating a backside metal (BSM) of the semiconductor device 1 of the embodiment, FIG. 5 is a plan view illustrating a bottom layer, and FIG. 6 is a plan view illustrating a top layer. BSM is an interconnect layer included in the first interconnect layer 7 on the back surface 301 of the substrate 3 (see FIG. 2), the bottom layer is a layer including the first transistor 11 of CFET provided on the front surface 302 side of the substrate 3, and the top layer is a layer including the second transistor 12 of CFET.

### PLAN ARRANGEMENT EXAMPLE OF BSM

In FIG. 4, TVDD 110, which is a first power supply line, and VVDD 120, which is a second power supply line, are arranged in a first direction (e.g., the X-direction) at a predetermined spacing in a region corresponding to the power switch circuit 20 on the first layer of the back surface (BSM1). VVDD 120 arranged in the X-direction on BSM1 of the power switch circuit 20 may be referred to as a segmented VVDD 120. In this example, the major axes of TVDD 110 and VVDD 120 are parallel to the X-direction, and TVDD 110 and VVDD 120 are arranged on the same line.

A power supply line 130 supplying a reference voltage lower than the operating voltage extends in the X-direction and is spaced apart from TVDD 110 and VVDD 120 by a predetermined distance in a second direction different from the first direction (e.g., -Y-direction). The power supply line 130 is a conductive wall which extends from the back surface of the substrate 3 to the height of the top transistor of CFET on the front surface side through the substrate 3. Hereinafter, the power supply line 130 is referred to as a “VSS sidewall 130”. The VSS sidewall 130 may be a conductive wall which extends from the front surface of the substrate 3 to the height of the top transistor of CFET. In this case, a through via formed in the substrate 3 may be connected to the VSS sidewall 130, and a reference voltage may be supplied to the VSS sidewall 130 via the through via. Further, the VSS sidewall 130 may be a conductive wall which extends to a position higher than the top transistor of CFET. In place of the VSS sidewall 130, a sidewall to which an operating voltage is supplied may be disposed, and a power supply line to which a reference voltage is supplied may be disposed on the back surface of the substrate 3. In the present invention, a direction indicated by an arrow indicating an X-direction or a Y-direction in the drawing is referred to as a plus (+) direction, and a direction opposite to the plus direction is referred to as a minus (−) direction.

In a region where the standard cell 10 is disposed, VVDD 120c extending continuously in the X-direction is disposed on the opposite side of TVDD 110 and the segmented VVDD 120, interposing the VSS sidewall 130 therebetween in the Y-direction. The standard cell 10 operates by receiving a power supply voltage from TVDD 110 to VVDD 120 and VVDD 120c by the power switch circuit 20. The standard cell 10 may be disposed in the same row as the segmented VVDD 120 adjacent to the power switch circuit 20 in the X-direction. In this arrangement as well, the power switch circuit 20 can be disposed close to the standard cell 10 where the VSS sidewall 130 is formed.

On a second layer of the back surface (BSM2) of the substrate 3, interconnects of TVDD, VVDD, and VSS (referred to as “TVDD BSM2”, “VVDD BSM2” and “VSS BSM2” respectively in the figure) are formed in the Y-direction crossing TVDD 110, VVDD 120, and the VSS sidewall 130. In the power switch circuit 20, TVDD 110 of the first layer (BSM1) is connected to the corresponding TVDD BSM2 of the second layer via via plugs 81b and 81d. The segmented VVDD 120 of the first layer (BSM1) of the power switch circuit 20 is connected to the corresponding VVDD BSM2 of the second layer via via plugs 81a, 81c, and 81e. The VSS sidewall 130 of the first layer (BSM1) is connected to VSS BSM2 of the second layer via a via plug 81i.

In the region of the standard cell 10, VVDD 120c continuous in the X-direction is connected to the corresponding VVDD BSM2 of the second layer via via plugs 81f, 81g, and 81h. When the supply of the power supply voltage from TVDD 110 to VVDD 120 is turned on in the power switch circuit 20, the power supply voltage is supplied from each VVDD 120 to VVDD 120c via the via plugs 81a, 81c, and 81e, VVDD BSM2, and the via plugs 81f, 81g, and 81h.

### PLANAR ARRANGEMENT EXAMPLE OF BOTTOM LAYER

FIG. 5 is a plan view illustrating the bottom layer on the front surface 302 of the substrate 3. The VSS sidewall 130 extending in the X-direction is a conductive wall extending through the substrate 3 to the height of CFET on the front surface 302 side. In the power switch circuit 20, a first semiconductor layer 111 is provided at a position overlapping TVDD 110 on the back surface in plan view, and a second semiconductor layer 112 is provided at a position overlapping the segmented VVDD 120. The first semiconductor layer 111 is connected to TVDD 110 on the back surface of the substrate 3 via a first through via 331 penetrating the substrate 3. The second semiconductor layer 112 is connected to VVDD 120 on the back surface of the substrate 3 via a second through via 332 penetrating the substrate 3.

A gate 131 is provided between the first semiconductor layer 111 and the second semiconductor layer 112 to form parallel-connected first transistors 11a to 11d (optionally collectively referred to as “first transistor 11”). The gate 131 extends in a direction perpendicular to the XY-plane and is commonly used for the first transistor 11 and the upper second transistor 12 (see FIG. 2). A first conductivity type (e.g., p-type) impurity is added to the first semiconductor layer 111 and the second semiconductor layer 112. The first transistor 11 functioning as the switch transistor 40 is turned on and off in accordance with a signal input to the gate 131. The entire first transistors 11a to 11d connected in parallel may be used as the switch transistor 40. By connecting a plurality of first transistors 11 in parallel, the size of the transistors can be increased to allow a large current to flow.

In the region of the standard cell 10, one of the semiconductor layers of the bottom transistor 21 is provided at a position coinciding with an intersection of VVDD 120c extending in the X-direction and VVDD BSM2 of the second layer extending in the Y-direction, in plan view. The other of the semiconductor layers of the bottom transistor 21 is provided at a position overlapping the intersection of VVDD 120c and the second layer TVDD BSM2 extending in the Y-direction. Which of the semiconductor layers of the bottom transistor of the standard cell 10 is used as the source or the drain depends on the design of the interconnect, but in the following description, for convenience, one semiconductor layer of the bottom transistor 21 is referred to as “source 211” and the other semiconductor layer is referred to as “drain 212”. The source 211 of the bottom transistor 21 is connected to VVDD 120c on the back surface 301 of the substrate 3 via a through via 342 penetrating the substrate 3. A gate 231 is provided between the source 211 and the drain 212 to form the bottom transistor 21. The gate 231 extends in the direction perpendicular to the XY-plane and is commonly used for the bottom transistor 21 and the top transistor 22 above. A first conductivity type (e.g., p-type) impurity is added to the source 211 and the drain 212.

When the voltage supply from TVDD 110 to VVDD 120 is turned on in the power switch circuit 20, a power supply voltage is supplied from VVDD 120 to the standard cell 10 via VVDD BSM2, VVDD 120c, and the through via 342. A signal routing interconnect 245 is connected to the drain 212. In this example, the interconnect 245 extends in the -Y-direction opposite to the VSS sidewall 130. The signal routing interconnect 245 is connected to the interconnect on the upper layer via a via plug 261.

With the arrangement shown in FIG. 5, the power switch circuit 20 including the switch transistor 40 can be arranged in the vicinity of the region of the standard cell 10 where the VSS sidewall 130 is formed.

### TOP LAYER PLAN CONFIGURATION EXAMPLE

FIG. 6 is a plan view illustrating a top layer on the front surface 302 of the substrate 3. In the power switch circuit 20, a third semiconductor layer 123 is disposed above the first semiconductor layer 111, and a fourth semiconductor layer 124 is disposed above the second semiconductor layer 112. The gate 131 used in common with the first transistor 11 is provided between the third semiconductor layer 123 and the fourth semiconductor layer 124, and second transistors 12a to 12d (collectively referred to as “second transistor 12”, as appropriate) connected in parallel in the X-direction are formed. The VSS sidewall 130 extending in the X-direction extends to the height of the second transistor 12. In the present invention, a portion that does not operate as a transistor, such as the second transistor 12, is also referred to as a transistor.

A second conductivity type (e.g., n-type) impurity different from the first conductivity type is added to the third semiconductor layer 123 and the fourth semiconductor layer 124 of the second transistor 12. The third semiconductor layer 123 and the fourth semiconductor layer 124 may be connected to the VSS sidewall 130, but in this example, they are floating.

The gates 131 of the second transistors 12a to 12d are connected to the interconnect 160-1 at a higher level via via plugs 161, 162, 163, and 164. A control signal output from the control circuit 30 is applied to the gate 131 via the interconnect 160-1 and the via plugs 161 to 164 at a higher level.

In the region of the standard cell 10, the top transistor 22 is disposed above the bottom transistor 21. One semiconductor layer of the top transistor 22 is provided above the source 211 of the bottom transistor 21, and the other semiconductor layer of the top transistor 22 is provided above the drain 212. Which of the semiconductor layers of the top transistor 22 is used as the source or the drain depends on the design of the interconnect. Here, for convenience, the semiconductor layers of the top transistor 22 are referred to as “a source 224” and “a drain 223”. The gate 231 used in common with the bottom transistor 21 is provided between the drain 223 and the source 224 to form a top transistor 22. CFET (see FIG. 2) arranged in a direction perpendicular to the substrate 3 is formed by the bottom transistor 21 below and the top transistor 22 above.

The source 224 of the top transistor 22 is connected to the VSS sidewall 130 via an interconnect 246 extending in the Y-direction. The drain 223 is electrically connected to an interconnect 160-2 on a higher layer via a via plug 262, and a signal of the top transistor 22 is routed. The gate 231 is electrically connected to an interconnect 160-3 on a higher layer via a via plug 263, and a gate voltage is applied thereto. The via plug 261 electrically connected to the drain 212 of the bottom transistor on a lower layer is connected to an interconnect 160-4 on a higher layer.

With this configuration, the power switch circuit 20 having the same CFET configuration and the switch transistor 40 in the bottom layer can be disposed near the standard cell 10 connected to the VSS sidewall 130.

### CROSS-SECTIONAL STRUCTURE

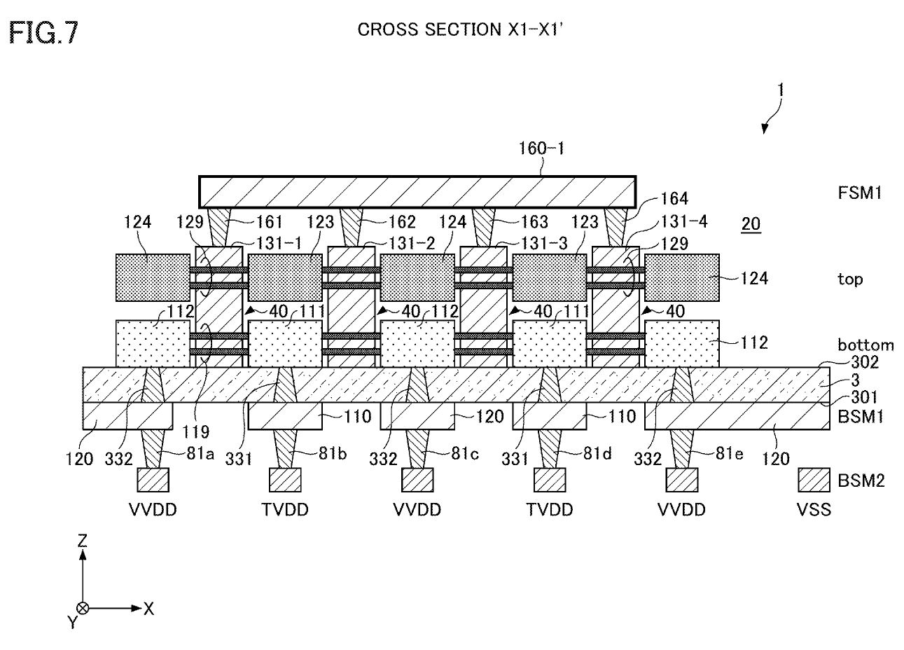

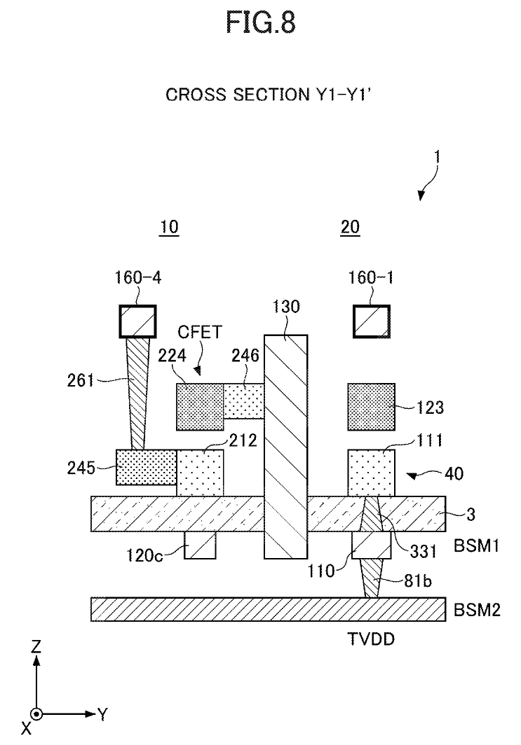

FIG. 7 is a cross-sectional view of FIGS. 4 to 6 taken along a line X1-X1′, and FIG. 8 is a cross-sectional view of FIGS. 4 to 6 taken along a line Y1-Y1′.

The cross section X1 – X1′ is a vertical cross section along TVDD 110 and VVDD 120 of the power switch circuit 20. The cross section taken along the line Y1-Y1′ is a vertical cross section along a line perpendicular to the line X1-X1′ and passing through the switch transistor 40 and the standard cell 10.

In the cross section X1-X1′ of FIG. 7, TVDD 110 and VVDD 120 are alternately arranged on the first layer (BSM1) of the back surface 301 of the substrate 3. TVDD 110 is connected to TVDD interconnect extending in the Y-direction on the second layer of the back surface (BSM2) via the via plugs 81b and 81d. VVDD 120 is connected to VVDD interconnect extending in the Y-direction on the second layer of the back surface (BSM2) via the via plugs 81a, 81c and 81e.

In the bottom layer on the front surface 302 side of the substrate 3, the first semiconductor layer 111 is provided at a position overlapping TVDD 110 in plan view, and the second semiconductor layer 112 is provided at a position overlapping VVDD 120. The first semiconductor layer 111 is connected to TVDD 110 via a first through via 331, and the second semiconductor layer 112 is connected to VVDD 120 via a second through via 332. The first semiconductor layer 111 and the second semiconductor layer 112 are connected via a channel 119 of a nanosheet.

In the top layer, a third semiconductor layer 123 is provided above the first semiconductor layer 111, and a fourth semiconductor layer 124 is provided above the second semiconductor layer 112. The third semiconductor layer 123 and the fourth semiconductor layer 124 are connected via a channel 129 of a nanosheet. Gates 131-1, 131-2, 131-3, and 131-4 extending from the surface of the substrate 3 to at least the height of the third semiconductor layer 123 and the fourth semiconductor layer 124 are provided between the first semiconductor layer 111 and the second semiconductor layer 112 adjacent in the X-direction, and between the third semiconductor layer 123 and the fourth semiconductor layer 124. The gates 131-1, 131-2, 131-3, and 131-4 (collectively referred to as “gate 131”, as appropriate) are electrically connected to the upper interconnect 160-1 via the via plugs 161, 162, 163, and 164.

The switch transistor 40 is formed of the first semiconductor layer 111, the second semiconductor layer 112, and the gate 131 provided between the first semiconductor layer 111 and the second semiconductor layer 112. When a gate voltage is applied from the interconnect 160-1 on the upper layer to the gates 131-1 to 131-4 via the via plugs 161, 162, 163, and 164, a power supply voltage is supplied from TVDD 110 to VVDD 120, and CFET of the standard cell 10 operates.

In the cross section taken along a line Y1-Y1′ of FIG. 8, the switch transistor 40 and the standard cell 10 of the power switch circuit 20 are arranged across the VSS sidewall 130. In the power switch circuit 20, the first semiconductor layer 111 of the switch transistor 40 is connected to TVDD 110 via a first through via 331 penetrating the substrate 3. TVDD 110 is connected to TVDD interconnect extending in the Y-direction on the second layer of the back surface (BSM2) via the via plug 81b. VVDD 120 is connected to VVDD interconnect extending in the Y-direction on the second layer of the back surface (BSM2) via the via plugs 81a, 81c, and 81e.

A third semiconductor layer 123 is provided above the first semiconductor layer 111, and an upper layer interconnect 160-1 is provided further above the third semiconductor layer 123. The upper layer interconnect 160-1 is connected to the gate of the switch transistor 40 as described with reference to FIG. 7.

In the standard cell 10, a semiconductor layer functioning as a drain 212 of a bottom transistor 21 (see FIG. 5) is provided at a position overlapping VVDD 120c in plan view, and a semiconductor layer functioning as a source 224 of the top transistor 22 (see FIG. 6) is provided above the drain 212. CFET is formed by the bottom transistor 21 and the top transistor 22 arranged in a direction perpendicular to the substrate 3.

A signal routing interconnect 245 is drawn out in the -Y-direction from the drain 212 of the bottom transistor and connected to an interconnect 160-4 on a higher layer via the via plug 261. The source 224 of the top transistor is connected to the VSS sidewall 130 via the interconnect 246 extending in the +Y-direction from the source 224. When a power supply voltage is applied from TVDD 110 to VVDD 120 (see FIG. 7) by the switch transistor 40 of the power switch circuit 20, CFET of the standard cell 10 operates.

By turning on and off the supply of the power supply voltage from TVDD 110 to VVDD 120 by the switch transistor, the power supply voltage can be supplied to the standard cell 10 when necessary to reduce power consumption.

### FIRST MODIFICATION EXAMPLE

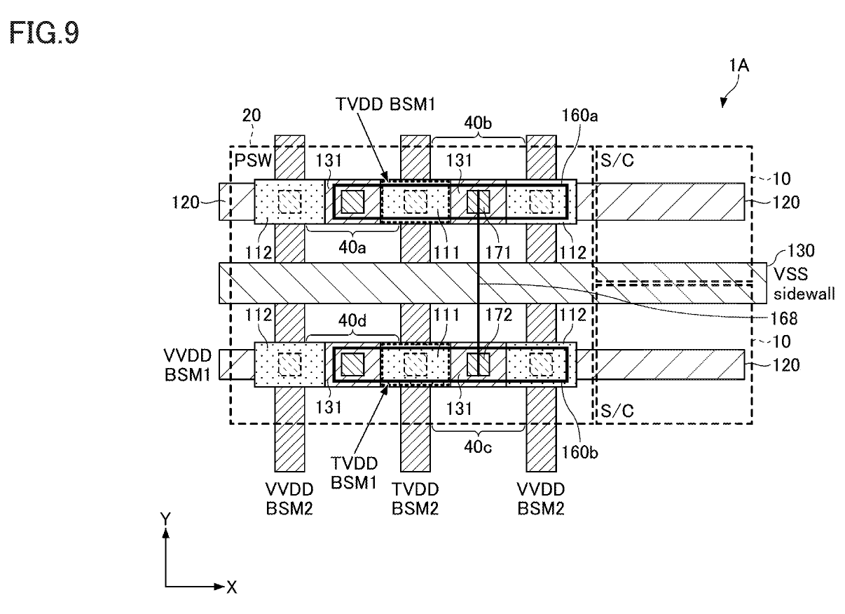

FIG. 9 is a plan view illustrating a bottom layer of a semiconductor device 1A of a first modification example. In the embodiment described above, the switch transistor 40 of the power switch circuit 20 is disposed opposite the standard cell 10 across the VSS sidewall 130. In the first modification, the switch transistor 40 is arranged on both sides in the Y-direction of the VSS sidewall 130 extending in the X-direction.

TVDD BSM1 is arranged between the segmented VVDD 120 on both sides of the VSS sidewall 130. In plan view, the first semiconductor layer 111 is provided at a position overlapping TVDD BSM1 on the back surface of the substrate 3, and the second semiconductor layer 112 is provided at a position overlapping VVDD 120. The gate 131 is provided between the first semiconductor layer 111 and the second semiconductor layer 112, and the switch transistor 40 is formed. As described with reference to FIG. 7, the first semiconductor layer 111 and the second semiconductor layer 112 are connected via the channel 119 formed of a nanosheet.

Switch transistors 40a and 40b are connected in parallel at the bottom layer on one side of the VSS sidewall 130, and switch transistors 40c and 40d are connected in parallel at the bottom layer on the other side of the VSS sidewall 130. The gate 131 of the switch transistor 40b and the gate 131 of the switch transistor 40c are connected via via plugs 171 and 172 and upper interconnect 168, and switch transistors 40a, 40b, 40c, and 40d (collectively referred to as “switch transistor 40”, as appropriate) are connected in parallel.

On each side of the VSS sidewall 130, the standard cell 10 is provided adjacent to the switch transistor 40 of the power switch circuit 20 in the X-direction. The standard cell 10 may be provided with, for example, CFET formed of the bottom transistor 21 and the top transistor 22 shown in FIGS. 5 and 6. The standard cell 10 operates when the supply of the power supply voltage from TVDD 110 to VVDD 120 is turned on in the switch transistor 40.

In the first modification example, the switch transistor 40 can also be provided near the VSS sidewall 130. In addition, the number of TVDD BSM2 in the second layer of the back surface for connecting TVDD interconnects of BSM1 in the first layer of the back surface of the substrate 3 can be reduced.

### SECOND MODIFICATION EXAMPLE

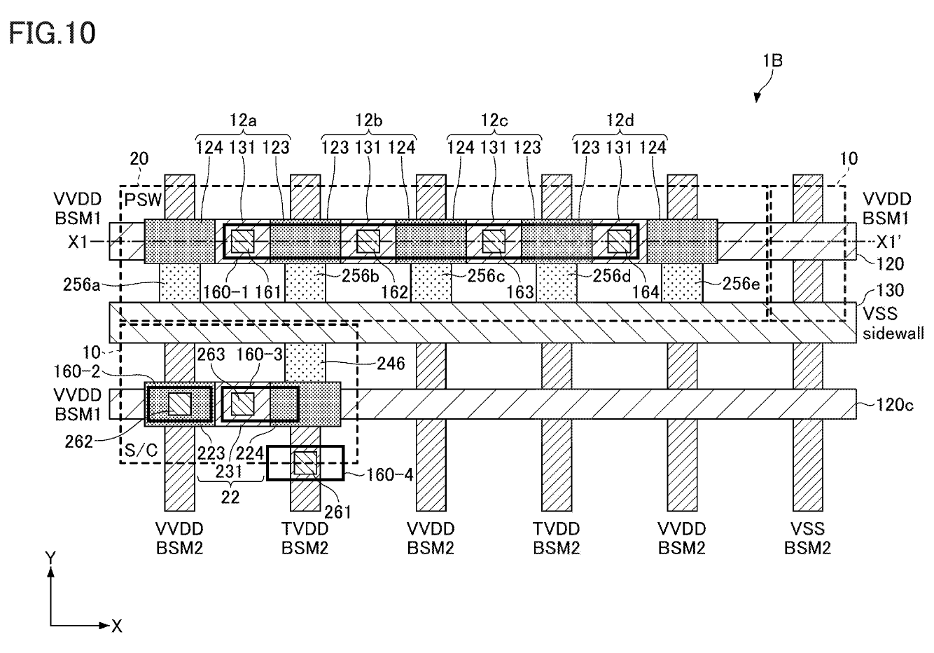

FIG. 10 is a plan view illustrating a top layer of a semiconductor device 1B of a second modification example. In the above-described embodiment, the third semiconductor layer 123 and the fourth semiconductor layer 124 are floating in each of the second transistors 12a to 12d provided above the first transistor 11 functioning as the switch transistor 40. In the second modification, the third semiconductor layer 123 and the fourth semiconductor layer 124 of the second transistors 12a to 12d are connected to the VSS sidewall 130 via interconnects 256a to 256e extending in the -Y-direction.

According to the configuration of the second modification, it is possible to reduce leakage current and an increase in power consumption caused by a voltage fluctuation in the source/drain of the second transistors 12a to 12d or the like.

Further, the present invention is not limited to these embodiments, and various variations and modifications may be made without departing from the scope of the present invention. In the configuration of FIG. 9 (first modification), the number of the first transistors 11 disposed on each side of the VSS sidewall 130 is not limited to two, and one or three or more first transistors may be provided as switch transistors. In this case, the gates of the first transistors 11 positioned at the extreme ends on each side of the VSS sidewall 130 may be connected to each other and connected in parallel. The configuration of the embodiment and the modified example provides an efficient layout of the power switch circuit 20, especially the switch transistor 40, when CFET is located in the vicinity of the VSS sidewall (or power wall).

What is claimed is:

1. A semiconductor device comprising: a substrate; a first power supply line and a second power supply line extending in a first direction in plan view on a first surface of the substrate; a first transistor disposed on a second surface of the substrate opposite to the first surface, the first transistor being electrically connected between the first power supply line and the second power supply line; a second transistor disposed above the first transistor, and sharing a gate with the first transistor; and a first conductive wall extending in the first direction and disposed offset from the first power supply line and the second power supply line in a second direction different from the first direction in plan view, wherein: in plan view, the first transistor includes a first semiconductor layer disposed at a position overlapping the first power supply line and a second semiconductor layer disposed at a position overlapping the second power supply line, with the gate interposed therebetween; the first semiconductor layer is electrically connected to the corresponding one of the first power supply lines via a first through via penetrating the substrate; and the second semiconductor layer is electrically connected to the corresponding one of the second power supply lines via a second through via penetrating the substrate.

2. The semiconductor device according to claim 1, wherein the second transistor includes: a third semiconductor layer disposed above the first semiconductor layer; and a fourth semiconductor layer disposed above the second semiconductor layer.

3. The semiconductor device according to claim 2, further comprising: a first interconnect extending in the second direction from the third semiconductor layer and electrically connecting the third semiconductor layer and the first conductive wall; and a second interconnect extending in the second direction from the fourth semiconductor layer and electrically connecting the fourth semiconductor layer and the first conductive wall.

4. The semiconductor device according to claim 1, wherein the first power supply line is disposed between two of the second power supply lines in the first direction.

5. The semiconductor device according to claim 1, wherein at least two of the second power supply lines and at least two of the first power supply lines are alternately disposed in the first direction.

6. The semiconductor device according to claim 5, wherein: a plurality of the first semiconductor layers and a plurality of the second semiconductor layers are alternately disposed; and a plurality of the first transistors are connected in parallel.

7. The semiconductor device according to claim 1, wherein: a plurality of the first transistors provided on each side of the first conductive wall in the second direction; and the gate of one of the first transistors provided on one side of the first conductive wall and the gate of another one of the first transistors provided on another side of the first conductive wall are electrically connected.

8. The semiconductor device according to claim 1, further comprising a standard cell disposed opposite the first transistor across the first conductive wall in the second direction, wherein the standard cell is connected to the first conductive wall.

9. The semiconductor device according to claim 1, wherein the first conductive wall extends to a height of the second transistor.
